(19) United States
(12) Patent Application Publication
(10) Pub. No.: US 2026/0314422 A1
(43) Pub. Date: Oct. 8, 2026

(54) SEMICONDUCTOR PACKAGE WITH STRESS-RELIEF STRUCTURES

(71) Applicant: SAMSUNG ELECTRONICS CO., LTD., Suwon-si (KR)

(72) Inventor: Hyejin KIM, Suown-si (KR)

(73) Assignee: SAMSUNG ELECTRONICS CO., LTD., Suwon-si (KR)

(21) Appl. No.: 19/462,161

(22) Filed: Jan. 28, 2026

(30) Foreign Application Priority Data
Feb. 5, 2025 (KR) 10-2025-0014714

(51) Int. Cl. H10W 42/00; H10W 74/15; H10W 90/00

(52) U.S. Cl. CPC H10W 42/121; H10W 74/15; H10W 90/701

(57) ABSTRACT

Provided is a semiconductor package including: a package substrate; an interposer substrate on a first surface of the package substrate; a first connection terminal between the package substrate and the interposer substrate; a first semiconductor device on the interposer substrate; and a second semiconductor device on the interposer substrate, wherein the second semiconductor device is spaced apart from the first semiconductor device in a horizontal direction, wherein the package substrate includes a first dummy hole extending in a vertical direction from the first surface of the package substrate, and wherein a distance from an edge of the package substrate adjacent to the first dummy hole is less than a distance from the edge to the first connection terminal.

### CROSS-REFERENCE TO RELATED APPLICATION

This application is based on and claims priority to Korean Patent Application No. 10-2025-0014714, filed on Feb. 5, 2025, in the Korean Intellectual Property Office, the disclosure of which is incorporated by reference herein in its entirety.

### BACKGROUND

The disclosure relates to a semiconductor package.

Along with the rapid development of the electronics industry and demands of users, electronic devices have become increasingly miniaturized and more lightweight. In accordance with the miniaturization and weight reduction of electronic devices, semiconductor packages used therein also have been increasingly miniaturized and more lightweight, and high integration of semiconductor devices has been demanded. To implement the high performance and the large capacity together with the miniaturization and the weight reduction, research and development have been continuously conducted on semiconductor chips including a through electrode and semiconductor packages in which such semiconductor chips are stacked. In a semiconductor package in which semiconductor chips are stacked, the reliability of stacking between the semiconductor chips has been demanded. In addition, deformation or warpage may occur between or in a heterogeneous interface of various materials stacked in a semiconductor package, and thus, technology for controlling the same has been demanded.

### SUMMARY

Provided is a reliable semiconductor package with reduced warpage.

According to an aspect of the disclosure, a semiconductor package includes: a package substrate; an interposer substrate on a first surface of the package substrate; a first connection terminal between the package substrate and the interposer substrate; a first semiconductor device on the interposer substrate; and a second semiconductor device on the interposer substrate, wherein the second semiconductor device is spaced apart from the first semiconductor device in a horizontal direction, wherein the package substrate includes a first dummy hole extending in a vertical direction from the first surface of the package substrate, and wherein a distance from an edge of the package substrate adjacent to the first dummy hole is less than a distance from the edge to the first connection terminal.

According to an aspect of the disclosure, a semiconductor package includes: a package substrate including an internal area and an edge area surrounding the internal area; an interposer substrate on a first surface of the package substrate, the interposer substrate including a capacitor; a first connection terminal between the package substrate and the interposer substrate; a first semiconductor device on the interposer substrate; and a second semiconductor device on the interposer substrate, wherein the first semiconductor device and the second semiconductor device are spaced apart in a horizontal direction, wherein the package substrate further includes a first dummy hole in the edge area, the first dummy hole extending in a vertical direction from the first surface of the package substrate, and wherein the interposer substrate further includes a second dummy hole between the first semiconductor device and the second semiconductor device in a top view, the second dummy hole extending in the vertical direction from an upper surface of the interposer substrate.

According to an aspect of the disclosure, a semiconductor package includes: a package substrate including: a core layer; an internal area; and an edge area; an interposer substrate on a first surface of the package substrate, the interposer substrate having a horizontal width less than a horizontal width of the package substrate; a first connection terminal connecting the interposer substrate and the package substrate in the internal area; a first semiconductor device and a second semiconductor device on the interposer substrate, the first semiconductor device and the second semiconductor device arranged in a horizontal direction; a second connection terminal between the interposer substrate and the first semiconductor device; and a third connection terminal between the interposer substrate and the second semiconductor device, wherein the package substrate further includes; a first dummy hole in the edge area, the first dummy hole extending in a vertical direction from the first surface of the package substrate; and a second dummy hole in the internal area, the second dummy hole extending in the vertical direction from the first surface of the package substrate, wherein the interposer substrate includes a third dummy hole between the second connection terminal and the third connection terminal, the third dummy hole extending in the vertical direction from an upper surface of the interposer substrate, and wherein the first dummy hole and the second dummy hole are spaced apart from the core layer.

In addition, the aspects and features of the disclosure are not limited to the foregoing, and other aspects and features may be clearly understood by those of ordinary skill in the art from the description below.

### BRIEF DESCRIPTION OF DRAWINGS

The above and other aspects and features of certain embodiments of the disclosure will be more clearly understood from the following detailed description taken in conjunction with the accompanying drawings, in which:

FIG. 1 is a cross-sectional view schematically illustrating a semiconductor package according to an embodiment;

FIGS. 2A, 2B, and 2C are top views illustrating a portion of a corner portion of a package substrate of a semiconductor package according to an embodiment;

FIGS. 3A, 3B, and 3C are cross-sectional views illustrating structures of a second semiconductor device in the semiconductor package of FIG. 1 in more detail;

FIG. 4 is a cross-sectional view schematically illustrating a semiconductor package according to an embodiment;

FIG. 5 is a cross-sectional view schematically illustrating a semiconductor package according to an embodiment;

FIG. 6 is a cross-sectional view schematically illustrating a semiconductor package according to an embodiment;

FIG. 7 is a cross-sectional view schematically illustrating a semiconductor package according to an embodiment; and

FIG. 8 is a cross-sectional view schematically illustrating a semiconductor package according to an embodiment.

### DETAILED DESCRIPTION

Hereinafter, embodiments are described in detail with reference to the accompanying drawings. Like reference numerals in the drawings denote like elements, and thus their repetitive description will be omitted.

In the embodiments below, the terms, such as “first” and “second” are not used as limited meanings but used to classify a certain element from another element. In the embodiments below, an expression in the singular includes an expression in the plural unless they are clearly different from each other in context.

In the specification, a first direction indicates the X direction, a second direction indicates the Y direction, and the first direction may be perpendicular to the second direction. A third direction is the Z direction and may be perpendicular to each of the first direction and the second direction. A horizontal surface or a plane indicates an X-Y plane.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

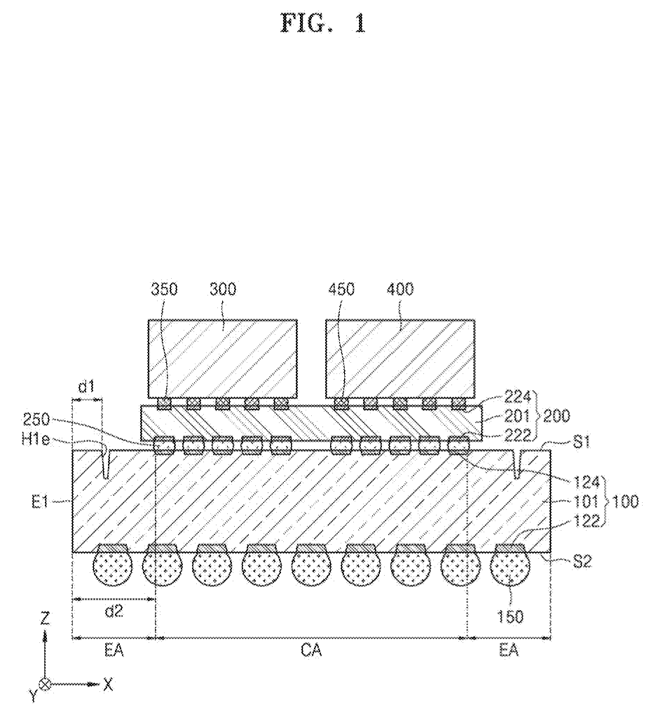

FIG. 1 is a cross-sectional view schematically illustrating a semiconductor package according to an embodiment.

Referring to FIG. 1, the semiconductor package according to an embodiment may include a package substrate 100, an interposer substrate 200, a first semiconductor device 300, and a second semiconductor device 400. The package substrate 100 may include a first dummy hole H1e.

The package substrate 100 may include, for example, a ceramic substrate, a printed circuit board (PCB), a glass substrate, an interposer substrate, or the like. In one or more embodiments, the package substrate 100 may include an active wafer, such as a silicon (Si) wafer. In the semiconductor package of an embodiment, the package substrate 100 may include a PCB. However, the package substrate 100 is not limited to the PCB.

The package substrate 100 may include a substrate body layer 101 and substrate pads. The substrate body layer 101 may form a body of the package substrate 100 and include a wiring layer therein. For example, when the package substrate 100 is a PCB, the substrate body layer 101 may include a core layer and a wiring layer. In one or more embodiments, the package substrate 100 may be a redistribution substrate. In this case, the substrate body layer 101 may not include a separate core layer but rather may include an interlayer insulating layer of a photo-imageable dielectric (PID) resin and multi-layer wirings.

A protective layer may be formed on the upper surface and the lower surface of the substrate body layer 101. The protective layer may include, for example, a solder resist (SR). However, the material of the protective layer is not limited to the SR.

The substrate pads may include upper substrate pads 124 on the upper surface of the substrate body layer 101 and lower substrate pads 122 on the lower surface of the substrate body layer 101. The upper substrate pads 124 may have a structure of passing through the protective layer on the upper surface of the substrate body layer 101. In addition, the lower substrate pads 122 may have a structure of passing through the protective layer on the lower surface of the substrate body layer 101. The upper substrate pads 124 and the lower substrate pads 122 may be individually connected to wirings of the substrate body layer 101. In addition, external connection terminals 150 may be respectively disposed on the lower substrate pads 122, and first connection terminals 250 may be respectively disposed on the upper substrate pads 124. In one or more embodiments, the substrate pads may be treated as portions of wirings of the wiring layer.

The external connection terminals 150 may connect the semiconductor package to a package substrate of an external system, a mainboard of an electronic device, such as a mobile device, or the like. The external connection terminal 150 may include a conductive material, for example, at least one of solder, tin (Sn), silver (Ag), copper (Cu), and aluminum (Al). However, the material of the external connection terminal 150 is not limited to the materials described above.

The interposer substrate 200 may be mounted on the package substrate 100 through the first connection terminals 250. The first connection terminal 250 may include, for example, a pillar and a bump. In one or more embodiments, the first connection terminal 250 may include only solder. The pillar may have a cylindrical shape and include, for example, nickel (Ni), Cu, palladium (Pd), platinum (Pt), gold (Au), or a combination thereof. In the semiconductor package of an embodiment, the pillar may include Cu.

The bump may be disposed on the pillar. The bump may include, for example, solder. The solder may include Sn, indium (In), bismuth (Bi), antimony (Sb), Cu, Ag, zinc (Zn), and/or an alloy thereof. For example, the solder may include Sn, Sn-Ag, Sn-Au, Sn-Cu, Sn-Bi, Sn-Zn, Sn-Ag-Cu, Sn-Ag-Bi, Sn-Ag-Zn, Sn-Cu-Bi, Sn-Cu-Zn, Sn-Bi-Zn, or the like. In one or more embodiments, the bump may be referred to as solder, a solder bump, or the like.

The interposer substrate 200 may be disposed on the package substrate 100. The interposer substrate 200 may be disposed between the package substrate 100 and the first semiconductor device 300 and between the package substrate 100 and the second semiconductor device 400. For example, the first semiconductor device 300 and the second semiconductor device 400 may be disposed on the interposer substrate 200, and the interposer substrate 200 may mediate signal transmission between the first semiconductor device 300 and the second semiconductor device 400. In addition, the interposer substrate 200 may mediate transmission of a signal, power, and the like between the first semiconductor device 300 and the package substrate 100 and between the second semiconductor device 400 and the package substrate 100.

The interposer substrate 200 may include an interposer body layer 201 and interposer pads 222 and 224. The interposer body layer 201 may include an insulating layer and wirings. The insulating layer may include an insulating polymer or an Si-based insulating material. The insulating layer may include multiple layers. As used herein, “providing to the inside of the interposer substrate 200” may indicate providing to the inside of the insulating layer. The wirings may be connected to the interposer pads.

The interposer pads may include upper interposer pads 224 on the upper surface of the interposer body layer 201 and lower interposer pads 222 on the lower surface of the interposer body layer 201. Second connection terminals 350 of the first semiconductor device 300 and third connection terminals 450 of the second semiconductor device 400 may be disposed on the upper interposer pads 224, respectively. The first connection terminals 250 may be disposed on the lower interposer pads 222, respectively.

In the semiconductor package of an embodiment, the interposer substrate 200 may be an interposer for a 2.5 dimensional (2.5D) package. As a reference, an interposer may largely include an interposer for a 2.5D package and an interposer for a 2.3D package. The interposer for a 2.5D package may commonly indicate an Si interposer and include a through-silicon via (TSV) therein. In addition, the interposer for a 2.3D package may indicate an organic or inorganic interposer. For the organic interposer, polyimide (PI), benzocyclobutene (BCB), or polybenzoxazole (PBO) may be used as a body layer, and for the inorganic interposer, ceramic or glass may be used as the body layer. When the interposer for a 2.3D package includes a through electrode, the through electrode may be referred to as a through dielectric via (TDV), a through glass via (TGV), or the like according to the material of the body layer.

In the package substrate 100 of the semiconductor package according to one or more embodiments, an internal area CA and an edge area EA may be defined. The internal area CA may approximately correspond to the central portion of the package substrate 100, and the edge area EA may correspond to the edge portion of the package substrate 100. The first connection terminal 250 may be disposed in the internal area CA but not be disposed in the edge area EA. The edge area EA may surround the internal area CA.

The package substrate 100 may include the first dummy hole H1e. The first dummy hole H1e may extend in a vertical direction from a first surface S1 of the package substrate 100. The first surface S1 may be the upper surface of the package substrate 100 adjacent to the interposer substrate 200. The first dummy hole H1e may have a shape in which a portion of the package substrate 100 is removed inward from the first surface S1 of the package substrate 100. The horizontal width of the first dummy hole H1e may gradually decrease inward from the first surface S1 of the package substrate 100.

Referring to FIG. 1, the first dummy hole H1e may be located in the edge area EA of the package substrate 100. In an embodiment, the package substrate 100 may have a horizontal width that is greater than that of the interposer substrate 200, and the first dummy hole H1e may be formed in a portion of the edge area EA, which does not vertically overlap the interposer substrate 200.

The distance from an edge of the package substrate adjacent to the first dummy hole H1e to the first dummy hole H1e may be less than the distance from the edge of the package substrate to the first connection terminal 250. For example, in an embodiment, the package substrate 100 may approximately have a quadrangular shape on a plane, and accordingly, the package substrate 100 may have four edges. The edge adjacent to the first dummy hole H1e may indicate an edge of the package substrate most adjacent to first dummy hole H1e among the four edges.

For example, in the first dummy hole H1e located to the left in the X direction in FIG. 1, a distance d1 from a first edge E1 adjacent to the first dummy hole H1e to the first dummy hole H1e may be less than a distance d2 from the first edge E1 to the first connection terminal 250. For example, the first dummy hole H1e may be closer to the first edge E1 than the first connection terminal 250. In an embodiment, the depth of the first dummy hole H1e may be about one micrometer to about 10,000 micrometers, inclusive. Alternatively, the depth of the first dummy hole H1e may be set to an appropriate value according to the thickness of the package substrate 100. In an embodiment, the thickness of the package substrate 100 may be less than the thickness of the interposer substrate 200.

As the internal structure of the semiconductor package is complicated, there may occur residual stress, such as interface delamination, due to a coefficient of thermal expansion (CTE) difference in a heterogeneous interface. For example, the CTE difference between the material of the package substrate 100 and the material of the interposer substrate 200 may be large, and thus, there may occur residual stress in the interface between the package substrate 100 and the interposer substrate 200. Accordingly, the package substrate 100 having a relatively thick and solid property may be bent, or cracks may occur in the package substrate 100.

The semiconductor package according to one or more embodiments may include the first dummy hole H1e in the first surface S1 of the package substrate 100 to alleviate stress occurring between the package substrate 100 and the interposer substrate 200. The first dummy hole H1e may be located in the edge area EA of the package substrate 100 to reduce design restrictions. In addition, because stiffness may be maintained by including a dummy hole instead of deploying a separate stiffness maintaining structure (e.g., a compressive dielectric) in the package substrate 100, an increase in the thickness and weight of the semiconductor package may be prevented.

In an embodiment, the first dummy hole H1e may be formed together in an operation of opening (or etching) a portion of the first surface S1 of the package substrate 100 to form the upper substrate pads 124. Accordingly, the first dummy hole H1e may be formed without a separate additional process.

The first semiconductor device 300 may be mounted on the interposer substrate 200 through the second connection terminals 350. In an embodiment, the first semiconductor device 300 may be disposed on a left portion of the interposer substrate 200 in the X direction. However, the position of the first semiconductor device 300 is not limited thereto.

The first semiconductor device 300 may have a chip or package structure. In the semiconductor package of the present embodiment, the first semiconductor device 300 may have a chip structure. For example, the first semiconductor device 300 may include a logic chip. The first semiconductor device 300 may include a plurality of logic devices therein. The plurality of logic devices may include, for example, an AND, a not AND (NAND), an OR, a not OR (NOR), an exclusive OR (XOR), an exclusive NOR (XNOR), an inverter (INV), an adder (ADD), a delay (DLY), a filter (FIL), a multiplexer (MXT/MXIT), an OR/AND/INV (OAI), an AND/OR (AO), an AND/OR/INV (AOI), a D flip-flop, a reset flip-flop, a master-slave flip-flop, a latch, a counter, and buffer devices. The plurality of logic devices may perform various kinds of signal processing, such as analog signal processing, analog-to-digital (A/D) conversion, and control. The first semiconductor device 300 may be referred to as a central processing unit (CPU) chip, a system on glass (SOG) chip, a micro-processor unit (MPU) chip, a graphics processing unit (GPU) chip, a neural processing unit (NPU) chip, an application processor (AP) chip, a control chip, or the like according to the function thereof.

In the semiconductor package of the present embodiment, the first semiconductor device 300 may have a chip structure, such as a system on chip (SoC) structure or a chiplet structure.

In addition, the first semiconductor device 300 may also include devices configured to support communication. However, in one or more embodiments, the devices configured to support communication may be separately provided as different chips, e.g., a modem chip, and disposed on the interposer substrate 200 in a structure of being coupled to the first semiconductor device 300.

The first semiconductor device 300 may include a first chip body and a first active layer. The first chip body may constitute a body of the first semiconductor device 300 and include Si. However, the material of the first chip body is not limited to Si. For example, the first chip body may include a different semiconductor material, such as germanium (Ge) or Si-Ge, or a Group III-V compound, such as gallium phosphide (GaP), gallium arsenide (GaAs), or gallium antimonide (GaSb). In addition, in one or more embodiments, the first chip body may include a silicon-on-insulator (SOI) substrate or a germanium-on-insulator (GOI) substrate.

The first active layer may be disposed beneath the first chip body and include a first integrated circuit layer and a first wiring layer. The first integrated circuit layer may include a plurality of first integrated circuits. The first integrated circuit may include, for example, a transistor. However, the first integrated circuit is not limited to the transistor. The first wiring layer may be disposed beneath the first integrated circuit layer. The first wiring layer may include an interlayer insulating layer, wirings, and a chip pad. The wirings may be disposed in two or more layers, and wirings in different layers may be connected to each other through a vertical via.

In the first semiconductor device 300, the lower surface may be a front surface that is an active surface, and the upper surface may be a back surface that is an inactive surface. In other words, a lower side of the first wiring layer with respect to the first chip body may correspond to the front surface of the first semiconductor device 300, and an upper surface side of the first chip body may correspond to the back surface of the first semiconductor device 300.

The second semiconductor device 400 may be mounted on the interposer substrate 200 through the third connection terminals 450. The second semiconductor device 400 may be disposed on a right portion of the interposer substrate 200 in the X direction. However, the position of the second semiconductor device 400 is not limited thereto. For example, when the first semiconductor device 300 is disposed on the right side of the interposer substrate 200 in the X direction, the second semiconductor device 400 may be disposed on the left side of the interposer substrate 200 in the X direction.

The second semiconductor device 400 may include logic devices or memory devices. When the second semiconductor device 400 includes logic devices, the second semiconductor device 400 may include devices configured to support communication of the first semiconductor device 300. For example, the second semiconductor device 400 may include a modem chip. However, the type of the second semiconductor device 400 is not limited to the modem chip. For example, the second semiconductor device 400 may include various types of logic devices configured to support an operation of the first semiconductor device 300 or perform various kinds of signal processing together with the first semiconductor device 300.

When the second semiconductor device 400 includes memory devices, the second semiconductor device 400 may include, for example, a volatile memory device, such as dynamic random access memory (DRAM) or static random access memory (SRAM), or a non-volatile memory chip, such as flash memory. In addition, when the second semiconductor device 400 includes memory devices, the second semiconductor device 400 may have a single-chip structure or a package structure.

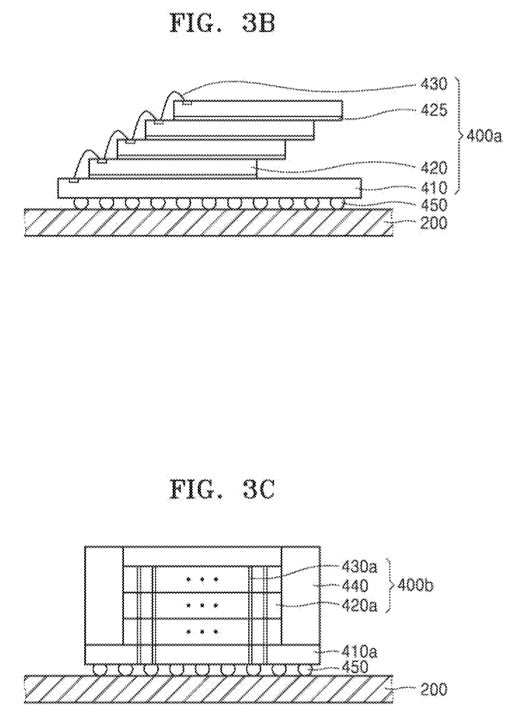

In the semiconductor package of the present embodiment, the second semiconductor device 400 may include, for example, a high bandwidth memory (HBM) package. However, the second semiconductor device 400 is not limited to a HBM package. For example, the second semiconductor device 400 may have a general package structure. For example, the second semiconductor device 400 may include an upper package substrate and a plurality of memory chips stacked on the upper package substrate. In addition, the plurality of memory chips may be stacked on the upper package substrate through a bonding wire or through a bump and a TSV. The single-chip structure or package structure of the second semiconductor device 400 is described in more detail with reference to FIGS. 3A-3C.

The second semiconductor device 400 may include a second chip body and a second active layer. The second chip body may constitute a body of the second semiconductor device 400 and include Si. However, the material of the second chip body is not limited to Si. The second active layer may be disposed beneath the second chip body and include a second integrated circuit layer and a second wiring layer. The second integrated circuit layer may include a plurality of second integrated circuits. The second integrated circuit may include, for example, a transistor. However, the second integrated circuit is not limited to a transistor. A detailed description of the second chip body and the second active layer is the same as the description made with respect to the first chip body and the first active layer of the first semiconductor device 300. In the second semiconductor device 400, the lower surface may be a front surface that is an active surface, and the upper surface may be a back surface that is an inactive surface. In other words, a lower side of the second wiring layer with respect to the second chip body may correspond to the front surface of the second semiconductor device 400, and an upper surface side of the second chip body may correspond to the back surface of the second semiconductor device 400.

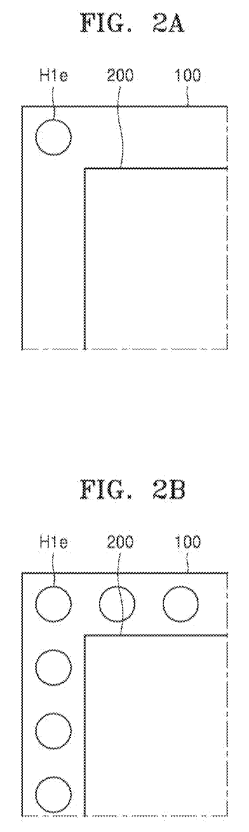

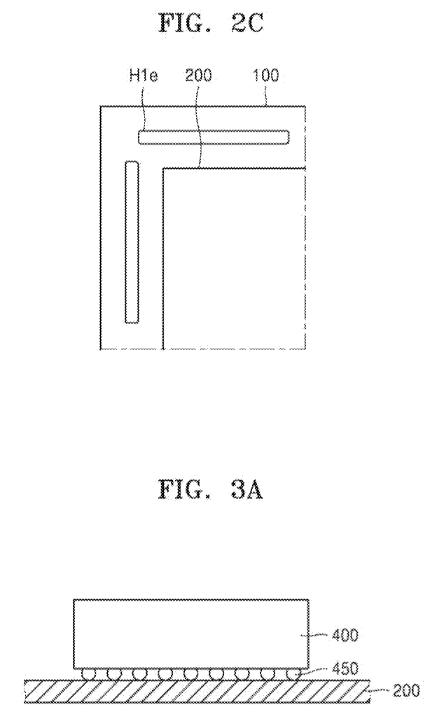

FIGS. 2A-2C are top views illustrating a portion of a corner portion of a package substrate of a semiconductor package according to an embodiment.

According to one or more embodiments, the first dummy hole H1e located in the edge area EA of the package substrate 100 may be located at a corner portion of the edge area EA of the package substrate 100. The corner portion may be a region where edges of the package substrate 100 extending in different directions meet.

Referring to FIGS. 2A-2C, the first dummy hole H1e may be circular or quadrangular on a plane, but the disclosure is not limited thereto. For example, the first dummy hole H1e may be polygonal, such as triangular, or oval on a plane. In an embodiment, the first dummy hole H1e may be formed as one hole at one corner portion, as shown in FIG. 2A, or arranged as a plurality of holes at one corner portion, as shown in FIG. 2B. Alternatively, as shown in FIG. 2C, holes extending along edges may be located at a corner portion.

FIGS. 3A-3C are cross-sectional views illustrating structures of a second semiconductor device in the semiconductor package of FIG. 1 in more detail. The description made with reference to FIG. 1 is simply repeated or omitted.

Referring to FIG. 3A, the second semiconductor device 400 may include one memory chip. The memory chip may include a volatile memory device, such as DRAM or SRAM, or a non-volatile memory device, such as flash memory. In an embodiment, the memory chip of the second semiconductor device 400 may include, for example, a DRAM chip. The second semiconductor device 400 may be mounted on the interposer substrate 200 through a flip-chip bonding structure using the third connection terminals 450. The third connection terminal 450 may include both a pillar and solder or include only the solder.

Referring to FIG. 3B, a second semiconductor device 400a may include a semiconductor package having a wire bonding structure. Particularly, the second semiconductor device 400a may include a package substrate 410 and a plurality of memory chips 420 stacked on the package substrate 410. The plurality of memory chips 420 may be mounted on the package substrate 410 through a wire bonding structure using an adhesive layer 425 and a wire 430. A memory chip 420 of the second semiconductor device 400a may include a volatile memory device, such as DRAM or SRAM, or a non-volatile memory device, such as flash memory. In the semiconductor package of the present embodiment, the memory chip 420 of the second semiconductor device 400a may include, for example, a DRAM chip. In addition, the second semiconductor device 400a may include, on the package substrate 410, an internal sealant that seals the plurality of memory chips 420 and the wire 430. However, for convenience, the internal sealant is omitted in FIG. 3B.

Although FIG. 3B shows that four memory chips 420 are stacked on the package substrate 410, the number of memory chips 420 is not limited to 4. For example, three or less or five or more memory chips 420 may be stacked on the package substrate 410. In addition, the plurality of memory chips 420 are not limited to a stepped structure and may be stacked on the package substrate 410 in a zigzag structure or a combination of the stepped structure and the zigzag structure. The third connection terminals 450 may be disposed on the lower surface of the package substrate 410. Therefore, the second semiconductor device 400a having a package structure may also be mounted on the interposer substrate 200 through the third connection terminals 450.

Referring to FIG. 3C, a second semiconductor device 400b may include an HBM package. Particularly, the second semiconductor device 400b may include a base chip 410a, a plurality of core chips 420a stacked on the base chip 410a, and an internal sealant 440. In addition, each of the base chip 410a and the plurality of core chips 420a may include a through electrode 430a therein. However, the uppermost core chip 420a among the plurality of core chips 420a may not include the through electrode 430a.

The base chip 410a may include logic devices. Accordingly, the base chip 410a may be a logic chip. The base chip 410a may be disposed beneath the plurality of core chips 420a, integrate signals of the plurality of core chips 420a and transmit the integrated signal to the outside, and transmit a signal and power from the outside to the plurality of core chips 420a. Accordingly, the base chip 410a may be referred to as a buffer chip or a control chip. Each of the plurality of core chips 420a may be a memory chip. For example, each of the plurality of core chips 420a may be a DRAM chip. Each of the plurality of core chips 420a may be stacked on the base chip 410a or a core chip 420a therebeneath through pad-to-pad bonding, hybrid bonding (HB), bonding using a connection terminal, bonding using an anisotropic conductive film (ACF), or the like. Although FIG. 3C shows that four core chips 420a are stacked on the base chip 410a, the number of core chips 420a is not limited to 4. For example, three or less or five or more core chips 420a may be stacked on the base chip 410a.

The third connection terminals 450 may be disposed on the lower surface of the base chip 410a. Therefore, the second semiconductor device 400b of the HBM package may also be mounted on the interposer substrate 200 through the third connection terminals 450. The plurality of core chips 420a on the base chip 410a may be sealed by the internal sealant 440. However, the upper surface of the uppermost core chip 420a among the plurality of core chips 420a may not be covered by the internal sealant 440. However, in one or more embodiments, the upper surface of the uppermost core chip 420a may be covered by the internal sealant 440.

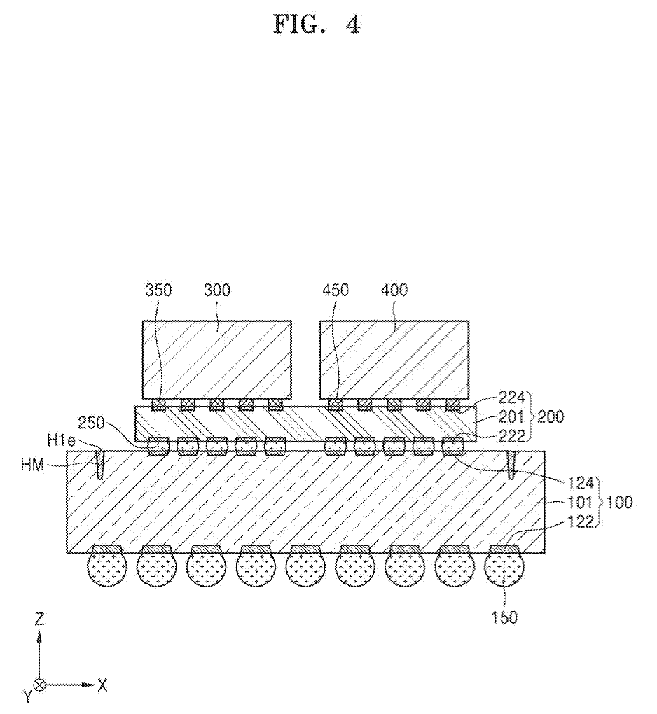

FIG. 4 is a cross-sectional view schematically illustrating a semiconductor package according to an embodiment. Like reference numerals in FIGS. 1 and 4 denote substantially like elements, and thus, their repetitive description is omitted, and the differences therebetween are mainly described.

Referring to FIG. 4, the semiconductor package according to an embodiment may include a metal layer HM filled in the first dummy hole H1e. The metal layer HM may fill the first dummy hole H1e by plating or with only a metal seed. In an embodiment, the metal layer HM may be isolated from the external connection terminals 150 and the first connection terminals 250. The metal layer HM may be isolated from the interposer substrate 200. The metal layer HM may not transfer a signal between an external device connected to the external connection terminals 150 and the interposer substrate 200. In an embodiment, the metal layer HM may be formed together with the upper substrate pads 124.

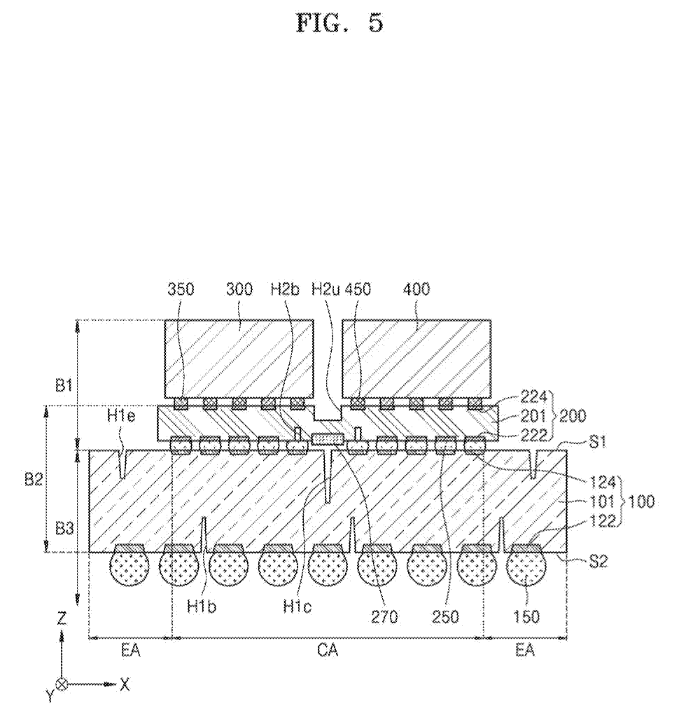

FIG. 5 is a cross-sectional view schematically illustrating a semiconductor package according to an embodiment. Like reference numerals in FIGS. 1 and 5 denote substantially like elements, and thus, their repetitive description is omitted, and the differences therebetween are mainly described.

The semiconductor package according to an embodiment may include a second dummy hole H1c. The second dummy hole H1c may extend in the vertical direction from the first surface S1 of the package substrate 100. The horizontal width of the second dummy hole H1c may gradually decrease inward from the first surface S1 of the package substrate 100.

Referring to FIG. 5, the second dummy hole H1c may be located in the internal area CA of the package substrate 100. In an embodiment, the second dummy hole H1c may be located between first connection terminals 250. The second dummy hole H1c may be located between the first semiconductor device 300 and the second dummy hole H1c on a plane. However, the disclosure is not limited thereto, and unlike FIG. 5, the second dummy hole H1c may be located to vertically overlap a first connection terminal 250, the first semiconductor device 300, or the second semiconductor device 400. The depth of the second dummy hole H1c may be about one micrometer to about 10,000 micrometers inclusive. Alternatively, the depth of the second dummy hole H1c may be set to an appropriate value according to the thickness of the package substrate 100. The second dummy hole H1c may alleviate mechanical stress due to the CTE difference between the package substrate 100 and the interposer substrate 200.

Referring to FIG. 5, the package substrate 100 may include a third dummy hole H1b. The third dummy hole H1b may extend in the vertical direction from a second surface S2 of the package substrate 100. The second surface S2 may be the lower surface of the package substrate 100 opposite to the first surface S1. The third dummy hole H1b may have a shape in which a portion of the package substrate 100 is removed inward from the second surface S2 of the package substrate 100. The horizontal width of the third dummy hole H1b may gradually decrease inward from the second surface S2 of the package substrate 100.

The depth of the third dummy hole H1b may be about one micrometer to about 10,000 micrometers inclusive. Alternatively, the depth of the third dummy hole H1b may be set to an appropriate value according to the thickness of the package substrate 100.

The third dummy hole H1b may be located in the edge area EA and/or the internal area CA of the package substrate 100. As shown in FIG. 5, third dummy holes H1b may be located between external connection terminals 150. Alternatively, the third dummy holes H1b may vertically overlap external connection terminals 150.

For example, the first dummy hole H1e and the second dummy hole H1c may prevent warpage of the package substrate 100 in the third direction (e.g., warpage of the edge area EA of the package substrate 100 in the -Z direction and warpage of the internal area CA of the package substrate 100 in the +Z direction), and the third dummy hole H1b may prevent warpage of the package substrate 100 in the third direction in a reverse manner (e.g., warpage in a smile shape). The third dummy hole H1b may alleviate residual stress due to temperature and stress concentration together with the first dummy hole H1e and the second dummy hole H1c, thereby preventing cracks in the external connection terminals 150.

The semiconductor package according to one or more embodiments may include a fourth dummy hole H2u. The fourth dummy hole H2u may extend in the vertical direction from the upper surface of the interposer substrate 200. The fourth dummy hole H2u may have a shape in which a portion of the interposer substrate 200 is removed inward from the upper surface of the interposer substrate 200. The horizontal width of the fourth dummy hole H2u may gradually decrease from the upper surface of the interposer substrate 200 into the interposer substrate 200. The depth of the fourth dummy hole H2u may be about one micrometer to about 10,000 micrometers inclusive. Alternatively, the depth of the fourth dummy hole H2u may be set to an appropriate value according to the thickness of the interposer substrate 200.

The fourth dummy hole H2u may be located above the internal area CA of the package substrate 100. The fourth dummy hole H2u may be located between the first semiconductor device 300 and the second semiconductor device 400. The fourth dummy hole H2u may be located between the second connection terminals 350 and the third connection terminals 450. Heat generated by the first semiconductor device 300 and the second semiconductor device 400 may be aggregated to a region between the first semiconductor device 300 and the second semiconductor device 400. The fourth dummy hole H2u may be located approximately between the first semiconductor device 300 and the second semiconductor device 400 to disperse heat of aggregation, which is generated by chips, and disperse warpage stress occurring in a heterogeneous interface between the interposer substrate 200 and the package substrate 100.

In an embodiment, the interposer substrate 200 may include a capacitor 270. The capacitor 270 may include a metal-insulator-metal (MIM) capacitor, an integrated stack capacitor (ISC), or a multi-layer ceramic capacitor (MLCC), but the disclosure is not limited thereto.

The interposer substrate 200 of the semiconductor package according to one or more embodiments may include a fifth dummy hole H2b. The fifth dummy hole H2b may extend in the vertical direction from the lower surface of the interposer substrate 200. The fifth dummy hole H2b may have a shape in which a portion of the interposer substrate 200 is removed inward from the lower surface of the interposer substrate 200. The horizontal width of the fifth dummy hole H2b may gradually decrease from the lower surface of the interposer substrate 200 into the interposer substrate 200.

The fifth dummy hole H2b may be located above the internal area CA of the package substrate 100. The fifth dummy hole H2b may be located adjacent to the capacitor 270. The fifth dummy hole H2b may disperse heat of aggregation generated by the capacitor 270. For example, the fifth dummy hole H2b may be located between the capacitor 270 and a first connection terminal 250 adjacent to the capacitor 270. Alternatively, the fifth dummy hole H2b may be located to vertically overlap the first connection terminal 250 adjacent to the capacitor 270.

In an embodiment, each of the second to fifth dummy holes H1c, H1b, H2u, and H2b may have a circular shape, an oval shape, a polygonal shape, such as a quadrangular shape, or the like, on a plane. In an embodiment, like the first dummy hole H1e of FIG. 4, the metal layer HM may be filled in the second to fifth dummy holes H1c, H1b, H2u, and H2b. Each of the second to fifth dummy holes H1c, H1b, H2u, and H2b may not electrically connect between the metal layer HM and an adjacent chip and/or substrate even when the metal layer HM is filled therein.

Referring to FIG. 5, the first dummy hole H1e, the second dummy hole H1c, and the third dummy hole H1b located in a section B3 may alleviate residual stress due to temperature and stress concentration in the semiconductor package, thereby protecting connection between the package substrate 100 and an external device connected to the external connection terminals 150. The first to fifth dummy holes H1e, H1c, H1b, H2u, and H2b located in a section B2 may disperse cracks and warpage stress due to the CTE difference between the material of the interposer substrate 200 and the material of the package substrate 100. The fourth dummy hole H2u and the fifth dummy hole H2b located in a section B1 may disperse heat of aggregation, which is generated by a chip and the like. Accordingly, the reliability of the semiconductor package including the package substrate 100, the interposer substrate 200, and the first and second semiconductor devices 300 and 400 may be improved, and the lifespan of the semiconductor package may be lengthened.

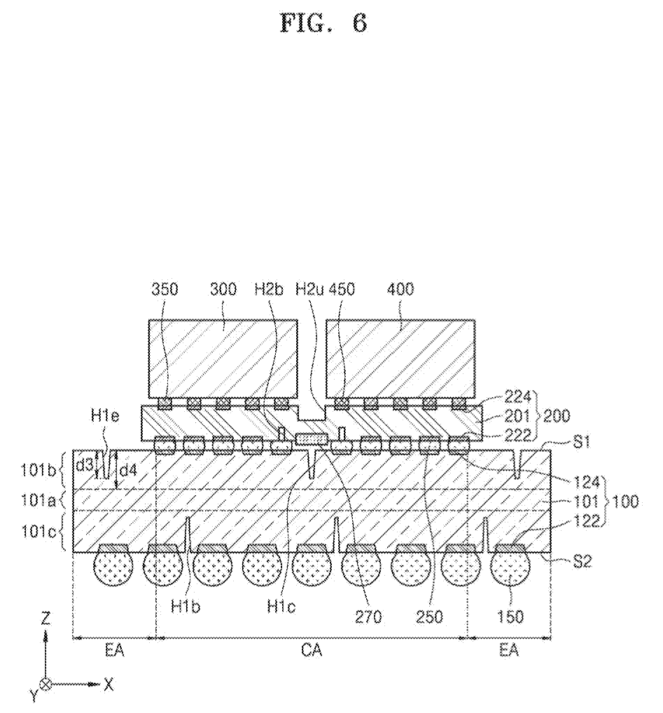

FIG. 6 is a cross-sectional view schematically illustrating a semiconductor package according to an embodiment. Like reference numerals in FIGS. 5 and 6 denote substantially like elements, and thus, their repetitive description is omitted, and the differences therebetween are mainly described.

Referring to FIG. 6, the substrate body layer 101 of the package substrate 100 may include a core layer 101a and wiring layers.

The core layer 101a is a layer forming a central structure of the package substrate 100 and may act as a base on which other layers are stacked. The core layer 101a may include a glass fiber, e.g., fire retardant class 4 (FR-4), and a resin. Alternatively, the core layer 101a may include a bismaleimide triazine (BT) resin, a polycarbonate (PC) resin, a build-up film, such as an Ajinomoto build-up film (ABF), or another laminate resin.

The wiring layers may be divided into an upper wiring layer 101b and a lower wiring layer 101c on either side of the core layer 101a. Each of the upper wiring layer 101b and the lower wiring layer 101c may include multi-layer wirings. The number of layers of the wirings of the upper wiring layer 101b may be the same as or different from the number of layers of the wirings of the lower wiring layer 101c. In an embodiment, the wiring layers may include 8-layer to 14-layer wirings. However, the number of layers of the wirings of the wiring layers is not limited thereto.

The wiring layers may include multi-layer wirings, an interlayer insulating layer insulating between the wirings, and a vertical via connecting wirings in different layers to each other. The wiring and the vertical via may include, for example, Cu. However, the material of the wiring and the vertical via is not limited to Cu. The interlayer insulating layer may include, for example, prepreg (PPG). Of course, the material of the interlayer insulating layer is not limited to PPG.

Referring to FIG. 6, a depth d3 of the first dummy hole H1e may be less than a distance d4 from the first surface S1 of the package substrate 100 to the core layer 101a. Likewise, the depth of the second dummy hole H1c may be less than the distance d4 from the first surface S1 (the upper surface) of the package substrate 100 to the core layer 101a. The depth of the third dummy hole H1b may be less than the distance from the second surface S2 (the lower surface) of the package substrate 100 to the core layer 101a.

Each of the first to third dummy holes H1e, H1c, and H1b may be spaced apart from the core layer 101a. For example, the first dummy hole H1e and the second dummy hole H1c may be formed by removing at least a portion of the upper wiring layer 101b, and the third dummy hole H1b may be formed by removing at least a portion of the lower wiring layer 101c. Each of the first to third dummy holes H1e, H1c, and H1b may not pass through the core layer 101a. Accordingly, the first to third dummy holes H1e, H1c, and H1b may alleviate residual stress in the semiconductor package and maintain the stiffness of the semiconductor package.

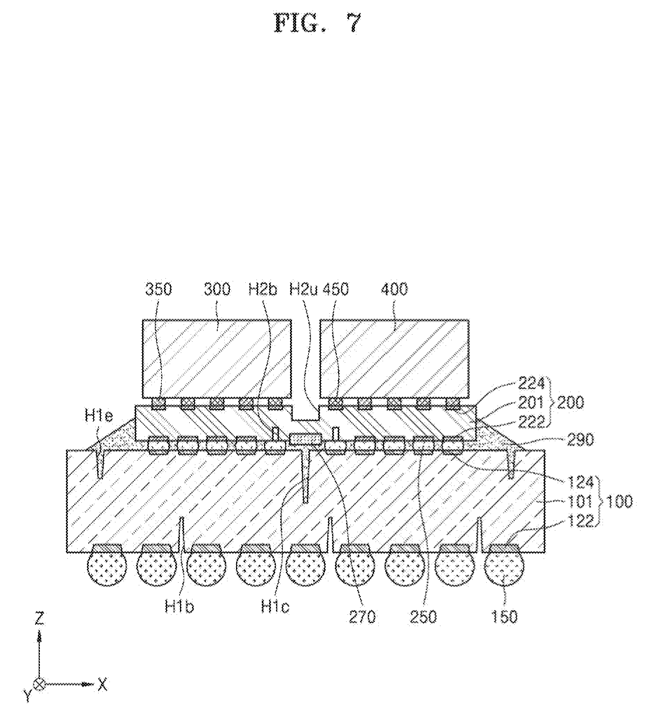

FIG. 7 is a cross-sectional view schematically illustrating a semiconductor package according to an embodiment. Like reference numerals in FIGS. 5 and 7 denote substantially like elements, and thus, their repetitive description is omitted, and the differences therebetween are mainly described.

Referring to FIG. 7, the semiconductor package according to an embodiment may include an underfill material layer 290. In an embodiment, the underfill material layer 290 may include a thermosetting resin, such as an epoxy resin, a thermoplastic resin, such as PI, or a resin containing a reinforcement material, such as an inorganic filler, in addition thereto, e.g., an ABF, an FR-4 resin, a BT resin, or the like. Alternatively, the underfill material layer 290 may include a molding material, such as an epoxy mold compound (EMC). However, the material of the underfill material layer 290 is not limited to the materials described above.

The underfill material layer 290 may surround the side surfaces of the first connection terminals 250. The underfill material layer 290 may fill the space between the interposer substrate 200 and the package substrate 100. In an embodiment, at least a portion of the underfill material layer 290 may fill the first dummy hole H1e and/or the second dummy hole H1c. In an embodiment, at least a portion of the underfill material layer 290 may fill the fifth dummy hole H2b. At least a portion of the underfill material layer 290 may be filled in the first, second, and fifth dummy holes H1e, H1c, and H2b, thereby improving the bonding force between the interposer substrate 200 and the package substrate 100.

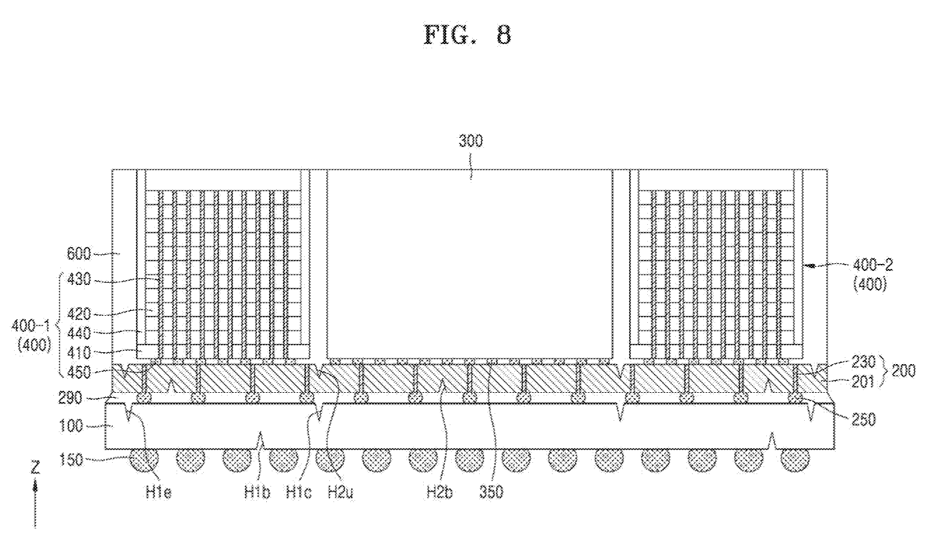

FIG. 8 is a cross-sectional view schematically illustrating a semiconductor package according to an embodiment.

Referring to FIG. 8, in the semiconductor package according to an embodiment, the first semiconductor device 300 may be disposed on the central portion of the interposer substrate 200 through the second connection terminals 350. The second semiconductor device 400 is the same as the second semiconductor device 400b described with reference to FIG. 3C. However, compared to the second semiconductor device 400b of FIG. 3C, the second semiconductor device 400 may include 12 core chips 420 (removing “a” from the reference numerals of components).

The package substrate 100 may include, in the upper surface of the package substrate 100, the first dummy hole H1e in an edge area of the package substrate 100 and the second dummy hole H1c in an internal area of the package substrate 100. The package substrate 100 may include the third dummy hole H1b in the lower surface of the package substrate 100. At least a portion of the underfill material layer 290 may be filled in the first dummy hole H1e and the second dummy hole H1c. The first to third dummy holes H1e, H1c, and H1b may alleviate warpage stress occurring in the package substrate 100 without increasing the thickness and weight of the package substrate 100. In addition, the depths of the underfill material layer 290 and the first to third dummy holes H1e, H1c, and H1b may be adjusted to maintain the stiffness of the package substrate 100 and the bonding force between the package substrate 100 and the interposer substrate 200.

The interposer substrate 200 may include the fourth dummy hole H2u formed in the upper surface of the interposer substrate 200 and the fifth dummy hole H2b formed in the lower surface of the interposer substrate 200. The fourth dummy hole H2u may be located between the first semiconductor device 300 and the second semiconductor device 400.

The semiconductor package according to an embodiment may include a sealant 600 sealing the first semiconductor device 300 and the second semiconductor device 400 on the interposer substrate 200. The sealant 600 may surround the side surfaces of the first semiconductor device 300 and the second semiconductor device 400. In an embodiment, the sealant 600 may not cover the upper surfaces of the first semiconductor device 300 and the second semiconductor device 400, as shown in FIG. 8. However, in one or more embodiments, the sealant 600 may cover the upper surface of at least one of the first semiconductor device 300 and the second semiconductor device 400. At least a portion of the sealant 600 may fill the fourth dummy hole H2u. That is, at least a portion of the sealant 600 may be filled in the fourth dummy hole H2u. By doing this, the bonding force between the internal components of the semiconductor package may be improved.

While the disclosure has been particularly shown and described with reference to embodiments thereof, it will be understood that various changes in form and details may be made therein without departing from the spirit and scope of the following claims.

What is claimed is:

1. A semiconductor package comprising:
a package substrate;
an interposer substrate on a first surface of the package substrate;
a first connection terminal between the package substrate and the interposer substrate;
a first semiconductor device on the interposer substrate; and
a second semiconductor device on the interposer substrate,
wherein the second semiconductor device is spaced apart from the first semiconductor device in a horizontal direction,
wherein the package substrate comprises a first dummy hole extending in a vertical direction from the first surface of the package substrate, and
wherein a distance from an edge of the package substrate adjacent to the first dummy hole is less than a distance from the edge to the first connection terminal.

2. The semiconductor package of claim 1, further comprising a plurality of first connection terminals comprising the first connection terminal,
wherein the plurality of first connection terminals are between the package substrate and the interposer substrate,
wherein the package substrate further comprises a second dummy hole extending in the vertical direction from the first surface of the package substrate, and
wherein the second dummy hole is between the plurality of first connection terminals.

3. The semiconductor package of claim 2, wherein the second dummy hole is between the first semiconductor device and the second semiconductor device in a top view.

4. The semiconductor package of claim 1, wherein the package substrate further comprises a third dummy hole extending in the vertical direction from a second surface of the package substrate, and
wherein the second surface is opposite to the first surface.

5. The semiconductor package of claim 4, further comprising a plurality of external connection terminals on the second surface of the package substrate,
wherein the third dummy hole is between the plurality of external connection terminals.

6. The semiconductor package of claim 4, wherein the package substrate further comprises:
a core layer;
an upper wiring layer on the core layer; and
a lower wiring layer beneath the core layer, and
wherein the first dummy hole and the third dummy hole do not pass through the core layer.

7. The semiconductor package of claim 1, wherein the interposer substrate comprises a fourth dummy hole extending in the vertical direction from an upper surface of the interposer substrate.

8. The semiconductor package of claim 7, wherein the fourth dummy hole is between the first semiconductor device and the second semiconductor device in a top view.

9. The semiconductor package of claim 7, further comprising a sealant on the interposer substrate,
wherein the sealant seals the first semiconductor device and the second semiconductor device, and
wherein at least a portion of the sealant is in the fourth dummy hole.

10. The semiconductor package of claim 1, wherein the interposer substrate further comprises: a capacitor; and a fifth dummy hole extending in the vertical direction from a lower surface of the interposer substrate.

11. The semiconductor package of claim 10, further comprising a plurality of first connection terminals comprising the first connection terminal,
wherein the plurality of first connection terminals are between the package substrate and the interposer substrate, and
wherein the fifth dummy hole is between the capacitor and at least one of the plurality of first connection terminals adjacent to the capacitor.

12. The semiconductor package of claim 10, wherein the fifth dummy hole vertically overlaps the first connection terminal.

13. The semiconductor package of claim 1, wherein the first dummy hole is at a corner portion where edges of the package substrate extending in different directions meet.

14. The semiconductor package of claim 1, further comprising an underfill material layer on a side surface of the first connection terminal,
wherein at least a portion of the underfill material layer is in the first dummy hole.

15. A semiconductor package comprising:
a package substrate comprising an internal area and an edge area surrounding the internal area;
an interposer substrate on a first surface of the package substrate, the interposer substrate comprising a capacitor;
a first connection terminal between the package substrate and the interposer substrate;
a first semiconductor device on the interposer substrate; and
a second semiconductor device on the interposer substrate,
wherein the first semiconductor device and the second semiconductor device are spaced apart in a horizontal direction,
wherein the package substrate further comprises a first dummy hole in the edge area, the first dummy hole extending in a vertical direction from the first surface of the package substrate, and
wherein the interposer substrate further comprises a second dummy hole between the first semiconductor device and the second semiconductor device in a top view, the second dummy hole extending in the vertical direction from an upper surface of the interposer substrate.

16. The semiconductor package of claim 15, wherein the package substrate further comprises:
a third dummy hole in the internal area of the package substrate, the third dummy hole extending in the vertical direction from the first surface of the package substrate; and
a fourth dummy hole extending in the vertical direction from a second surface of the package substrate, and
wherein the second surface is opposite to the first surface.

17. The semiconductor package of claim 16, wherein the interposer substrate further comprises a fifth dummy hole, and
wherein the fifth dummy hole extends in the vertical direction from a lower surface of the interposer substrate and is adjacent to the capacitor.

18. The semiconductor package of claim 17, further comprising a metal layer in at least one of the first dummy hole, the second dummy hole, the third dummy hole, the fourth dummy hole, or the fifth dummy hole.

19. The semiconductor package of claim 17, further comprising:
an underfill material layer on a side surface of the first connection terminal; and
a sealant on the interposer substrate and on a side surface of the first semiconductor device and a side surface of the second semiconductor device,
wherein at least a portion of the underfill material layer is in the first dummy hole and the third dummy hole, and at least a portion of the sealant is in the second dummy hole.

20. A semiconductor package comprising:
a package substrate comprising: a core layer; an internal area; and an edge area;
an interposer substrate on a first surface of the package substrate, the interposer substrate having a horizontal width less than a horizontal width of the package substrate;
a first connection terminal connecting the interposer substrate and the package substrate in the internal area;
a first semiconductor device and a second semiconductor device on the interposer substrate, the first semiconductor device and the second semiconductor device arranged in a horizontal direction;
a second connection terminal between the interposer substrate and the first semiconductor device; and
a third connection terminal between the interposer substrate and the second semiconductor device,
wherein the package substrate further comprises;
a first dummy hole in the edge area, the first dummy hole extending in a vertical direction from the first surface of the package substrate; and
a second dummy hole in the internal area, the second dummy hole extending in the vertical direction from the first surface of the package substrate,
wherein the interposer substrate comprises a third dummy hole between the second connection terminal and the third connection terminal, the third dummy hole extending in the vertical direction from an upper surface of the interposer substrate, and
wherein the first dummy hole and the second dummy hole are spaced apart from the core layer.
